(19) United States
(12) Patent Application Publication
(10) Pub. No.: US 2025/0333595 A1
(43) Pub. Date: Oct. 30, 2025

(54) RESIN COMPOSITION

(71) Applicant: NAN YA PLASTICS CORPORATION, Taipei City (TW)

(72) Inventors: Ching-Yao Yuan, Taipei City (TW); Li Yun Chen, Taipei City (TW); Wei-Ru Huang, Taipei City (TW); Hung-Yi Chang, Taipei City (TW); Chia-Lin Liu, Taipei City (TW)

(73) Assignee: NAN YA PLASTICS CORPORATION, Taipei City (TW)

(21) Appl. No.: 18/666,782

(22) Filed: May 16, 2024

(30) Foreign Application Priority Data
Apr. 25, 2024 (TW) 113115422

(51) Int. Cl. C08L 67/00; C08K 7/18; H05K 1/03

(52) U.S. Cl. CPC C08L 67/00; C08K 7/18; H05K 1/0373

(57) ABSTRACT

A resin composition includes an epoxy resin, an active ester compound, a free radical polymerizable resin, an inorganic filler material, and an accelerator. The free radical polymerizable resin includes an olefin compound. The olefin compound includes a methacrylic compound, a styrene compound, an allyl compound, or a combination thereof.

### CROSS-REFERENCE TO RELATED APPLICATION

This application claims the priority benefit of Taiwan application serial no. 113115422, filed on Apr. 25, 2024. The entirety of the above-mentioned patent application is hereby incorporated by reference herein and made a part of this specification.

### BACKGROUND

### Technical Field

The disclosure relates to a resin composition.

### Description of Related Art

In recent years, with the rapid development of integrated circuit (IC) technology, requirements such as wiring density (L/S) and transmission rate of chips (for example, high-speed computing chips) have increased, and in order to be more suitable for applications in the field of high-frequency fast transmission, the electrical requirements for a resin composition are also increasing.

### SUMMARY

The disclosure provides a resin composition, which can optimize the electrical performance of an epoxy resin system and simultaneously meet the requirements for copper-clad adhesion and film-forming properties.

A resin composition of the disclosure includes an epoxy resin, an active ester compound, a free radical polymerizable resin, an inorganic filler material, and an accelerator. The free radical polymerizable resin includes an olefin compound. The olefin compound includes a methacrylic compound, a styrene compound, an allyl compound, or a combination thereof.

In an embodiment of the disclosure, the free radical polymerizable resin is selected from at least two of the methacrylic compound, the styrene compound, and the allyl compound.

In an embodiment of the disclosure, at least one compound in the free radical polymerizable resin is the methacrylic compound.

In an embodiment of the disclosure, a weight proportion of the methacrylic compound in the resin composition is between 1 wt % and 10 wt %.

In an embodiment of the disclosure, a weight proportion of the epoxy resin in the resin composition is between 5 wt % and 15 wt %, a weight proportion of the active ester compound in the resin composition is between 10 wt % and 20 wt %, a weight proportion of the inorganic filler material in the resin composition is greater than 60 wt %, a weight proportion of the free radical polymerizable resin in the resin composition is between 1 wt % and 20 wt %, and a weight proportion of the accelerator in the resin composition is between 0.1 wt % and 0.5 wt %.

In an embodiment of the disclosure, the epoxy resin includes a biphenyl aralkyl type epoxy resin, a bisphenol A type epoxy resin, or a combination thereof, the active ester compound includes a polyester resin, the inorganic filler material includes spherical silica, and the accelerator includes 4-dimethylaminopyridine.

In an embodiment of the disclosure, a usage amount of the inorganic filler material in the resin composition is greater than a usage amount of the epoxy resin, the active ester compound, the free radical polymerizable resin, and the accelerator in the resin composition.

In an embodiment of the disclosure, a usage amount of the free radical polymerizable resin in the resin composition is greater than a usage amount of the accelerator in the resin composition.

In an embodiment of the disclosure, a usage amount of the free radical polymerizable resin in the resin composition is less than a usage amount of the epoxy resin in the resin composition.

In an embodiment of the disclosure, the olefin compound includes a methacrylate polyphenylene ether resin, a hydrogenated styrenic elastomer, a vinyl benzyl polyphenylene ether resin, a hydrocarbon resin, a polybutadiene resin, or a combination thereof.

Based on the above, in the disclosure, the free radical polymerizable resin is introduced into the resin composition to reduce the number of polar functional groups contained in the epoxy resin system. In this way, the dielectric properties can be effectively reduced, thereby optimizing the electrical performance of the epoxy resin system and simultaneously meeting the requirements for copper-clad adhesion and film-forming properties.

In order for the features and advantages of the disclosure to be more comprehensible, the following specific embodiments are described in detail in conjunction with the drawings.

### DESCRIPTION OF THE EMBODIMENTS

In the following detailed description, for purposes of illustration and not limitation, exemplary embodiments disclosing specific details are set forth in order to provide a thorough understanding of various principles of the disclosure. However, it will be apparent to persons of ordinary skill in the art that the disclosure may be practiced in other embodiments that depart from the specific details disclosed herein, having the benefit of the disclosure.

Unless otherwise stated, the term “between” used in the specification to define a value range is intended to cover a range equal to the stated endpoint values and between the stated endpoint values. For example, a size range between a first value and a second value means that the size range may cover the first value, the second value, and any value between the first value and the second value.

Unless otherwise defined, all terms (including technical and scientific terms) used herein have the same meaning as commonly understood by persons of ordinary skill in the art to which the disclosure belongs.

In the embodiment, a resin composition includes an epoxy resin, an active ester compound, a free radical polymerizable resin, an inorganic filler material, and an accelerator.

Furthermore, the free radical polymerizable resin includes an olefin compound (having unsaturated bonds), wherein the olefin compound includes a methacrylic compound, a styrene compound, an allyl compound, or a combination thereof. Accordingly, in the embodiment, the free radical polymerizable resin is introduced into the resin composition to reduce the number of polar functional groups contained in the epoxy resin system. In this way, the dielectric properties can be effectively reduced, thereby optimizing the electrical performance of the epoxy resin system and simultaneously meeting the requirements for copper-clad adhesion and film-forming properties.

In some embodiments, the olefin compound includes a methacrylate polyphenylene ether resin, a hydrogenated styrenic elastomer, a vinyl benzyl polyphenylene ether resin, a hydrocarbon resin, a polybutadiene resin, or a combination thereof, but the disclosure is not limited thereto.

In some embodiments, the free radical polymerizable resin is selected from at least two of the methacrylic compound, the styrene compound, and the allyl compound to have improved dielectric properties, but the disclosure is not limited thereto.

In some embodiments, at least one compound in the free radical polymerizable resin is the methacrylic compound, such as the methacrylate polyphenylene ether resin, and a weight proportion of the methacrylic compound in the resin composition is between 1 wt % and 10 wt % (for example, 1 wt %, 3 wt %, 5 wt %, 10 wt %, or any appropriate value between 1 wt % and 10 wt %), but the disclosure is not limited thereto.

In some embodiments, a weight proportion of the free radical polymerizable resin in the resin composition is between 1 wt % and 20 wt % (for example, 1 wt %, 5 wt %, 10 wt %, 15 wt %, 20 wt %, or any appropriate value between 1 wt % to 20 wt %), but the disclosure is not limited thereto.

In some embodiments, the epoxy resin includes a biphenyl aralkyl type epoxy resin (for example, a naphthylene ether type epoxy resin), a bisphenol A type epoxy resin, or a combination thereof, wherein a weight proportion of the epoxy resin in the resin composition is between 5 wt % and 15 wt % (for example, 5 wt %, 7 wt %, 10 wt %, 12 wt %, 15 wt %, or any appropriate value between 5 wt % and 15 wt %), but the disclosure is not limited thereto.

In some embodiments, the active ester compound includes a polyester resin, wherein a weight proportion of the active ester compound in the resin composition is between 10 wt % and 20 wt % (for example, 10 wt %, 12 wt %, 15 wt %, 17 wt %, 20 wt %, or any appropriate value between 10 wt % and 20 wt %), but the disclosure is not limited thereto.

In some embodiments, the inorganic filler material includes spherical silica, wherein a weight proportion of the inorganic filler material in the resin composition is greater than 60 wt %, but the disclosure is not limited thereto. Here, a median particle size (D₅₀) of the inorganic filler material may be less than 1 micrometer or any other appropriate value.

In some embodiments, the inorganic filler material is prepared by a synthesis method, so that the inorganic filler material contains an epoxy-based or acrylic-based surface modification to improve performance, wherein the synthesis method is, for example, a solid-state synthesis method, but the disclosure is not limited thereto.

In some embodiments, a purity of the inorganic filler material is greater than or equal to 99%, but the disclosure is not limited thereto.

In some embodiments, a specific surface area of the inorganic filler material is between 4 m²/g and 6 m²/g to control a contact area with a functional group to be within a preferred range so that preferred low dielectric properties can be maintained, such as Dk of between 3 and 3.3, and Df of less than or equal to 0.0025, but the disclosure is not limited thereto. The specific surface area of the inorganic filler material may be determined according to actual design requirements.

In some embodiments, the accelerator includes 4-dimethylaminopyridine, wherein a weight proportion of the accelerator in the resin composition is between 0.1 wt % and 0.5 wt %, but the disclosure is not limited thereto.

In some embodiments, a usage amount of the inorganic filler material in the resin composition is greater than a usage amount of the epoxy resin, the active ester compound, the free radical polymerizable resin, and the accelerator in the resin composition, but the disclosure is not limited thereto.

In some embodiments, a usage amount of the free radical polymerizable resin in the resin composition is greater than a usage amount of the accelerator in the resin composition and/or the usage amount of the free radical polymerizable resin in the resin composition is less than the usage amount of the epoxy resin in the resin composition, but the disclosure is not limited thereto.

In some embodiments, a sum of the weight proportions of the epoxy resin, the active ester compound, the free radical polymerizable resin, the inorganic filler material, and the accelerator in the resin composition is 100 wt %, but the disclosure is not limited thereto.

It should be noted that the resin composition may be regarded as a non-volatile component of a resin composition (varnish form) dissolved in a solvent, but the disclosure is not limited thereto. In addition, the resin composition of the disclosure may be processed into a prepreg and a copper clad laminate (CCL) according to actual design requirements, and the specific implementation forms listed above are not limitations of the disclosure.

The following examples and comparative examples are given to illustrate the effects of the disclosure, but the claims of the disclosure are not limited to the scope of the examples.

A product of each example and comparative example was evaluated according to the following method.

Glass transition temperature (Tg) (° C.): the glass transition temperature Tg (° C.) of a material was measured using a thermomechanical analyzer (TMA) according to a standard test method of ASTM E1545.

Coefficient of thermal expansion (CTE) (x-y plane direction): the coefficient of thermal expansion of a X-Y plane, that is, X-Y CTE (ppm/° C.) of the material was measured using a thermomechanical analyzer (TMA) according to a standard test method of IPC-TM-650 2.4.24. A temperature rising range condition of the test was 25° C. to 150° C.

Dielectric constant Dk/dissipation factor Df: a resin film made of a resin composition shown in Table 1 was heated at 200° C. for 90 minutes to form a cured film. The cured film was cut into a size with a length of 10 mm and a width of 7 mm. The dielectric constant (Dk, ε r) and the dissipation factor (Df, Tan δ) of the material under a 10 GHz signal were measured according to a standard test method of IPC-TM-650 (Method 2.5.5.3).

Resin sheet material lamination and curing: a glass cloth epoxy resin base material with a copper foil was prepared as an inner substrate, two surfaces were cladded with copper lamination (“NPG-180INBK” manufactured by Nan Ya Plastics Corporation), and the surface copper foil of the inner substrate was roughened. The resin composition and the inner substrate were bonded through a vacuum laminator using the vacuum laminator (“V-130” manufactured by Nikko-Material Co., Ltd.). The conditions were: after reducing the pressure to less than 1 hPa for 30 seconds, pressing was performed for 60 seconds under the conditions of temperature 100° C./pressure 100N. Subsequently, the resin composition was heated in an oven at 130° C. for 30 minutes, and then moved to an oven to be heated at 165° C. for 30 minutes. The resin composition was cured through the heating, and a substrate A was obtained.

Copper-clad adhesion: the evaluation substrate A obtained after the vacuum laminator and heat curing, ⊚: was stably adhered without falling off, X: fell off after baking.

Film-forming properties: the resin composition was mixed in a solvent (solid weight 65 wt %), the same was coated on a support (PET film) using a die coater, after drying to form a film, the same was placed at a temperature of 200° C. for 90 minutes, ⊚: a complete film surface was obtained after hardening, X: a complete film surface was not obtained after hardening.

### Examples 1 to 5 and Comparative Example 1

The resin composition shown in Table 1 was dissolved in a solvent (toluene, butanone, cyclohexanone), the same was coated on a support (PET film) using a die coater, after drying to form a film layer, properties such as the glass transition temperature, the coefficient of thermal expansion, the dielectric constant, and the dissipation factor were evaluated, and the copper-clad adhesion and the film-forming properties were tested with the above manners. The results are shown in Table 1. After comparing the results of Examples 1 to 5 and Comparative Example 1 in Table 1, the following conclusions may be drawn. Compared with Comparative Example 1, Examples 1 to 5 that used the free radical polymerizable resin can optimize the electrical performance of the epoxy resin system and simultaneously meet the requirements for copper-clad adhesion and film-forming properties.

TABLE 1

| | Comparative | | | | | |
|---|---|---|---|---|---|---|
| | Example | Example | | | | |
| | 1 | 1 | 2 | 3 | 4 | 5 |
| Epoxy resin (NC3500) (parts by mass) | 6.25 | 6.25 | 4.2 | 4.2 | 4.2 | 6.25 |
| Epoxy resin (NPEL-170) (parts by mass) | 6.25 | 6.25 | 6 | 6 | 6 | 6.25 |
| Active ester compound | 20 | 18.85 | 18.85 | 18.85 | 18.85 | 18.85 |
| (HPC-8150) (parts by mass) | | | | | | |
| Free radical polymerizable resin | 0 | 3.6 | 3.45 | 3.45 | 3.45 | 3.45 |
| (SA-9000) (parts by mass) | | | | | | |
| Free radical polymerizable resin | 0 | 0 | 1.72 | 0 | 0 | 0 |
| (MP-10) (parts by mass) | | | | | | |
| Free radical polymerizable resin | 0 | 0 | 0 | 1.72 | 0 | 0 |
| (OPE-2St 1200) (parts by mass) | | | | | | |
| Free radical polymerizable resin | 0 | 0 | 0 | 0 | 1.72 | 0 |
| (LDM-03, Denka) (parts by mass) | | | | | | |
| Free radical polymerizable resin | 0 | 0 | 0 | 0 | 0 | 1.72 |
| (RI-257) (parts by mass) | | | | | | |
| First filler of inorganic filler material | 100 | 100 | 100 | 100 | 100 | 100 |
| (EQH0610-SES, D50 = 0.6 | | | | | | |
| micrometers, Third Age) (parts by mass) | | | | | | |
| Accelerator (DMAP) (parts by mass) | 0.2 | 0.2 | 0.2 | 0.2 | 0.2 | 0.2 |
| Glass transition temperature (° C.) | 172 | 167 | 160 | 165 | 165 | 162 |
| X-Y coefficient of thermal expansion | 13.55 | 13.35 | 17 | 16.5 | 17.2 | 17.8 |
| (25° C. to 150° C.) (ppm/° C.) | | | | | | |
| Dk/Df (10 GHz) | 3.3/0.004 | 3.2/0.0025 | 3.3/0.0024 | 3.3/0.0025 | 3.3/0.0023 | 3.3/0.0025 |
| Copper-clad adhesion | ⊚ | ⊚ | ⊚ | ⊚ | ⊚ | ⊚ |
| Film-forming properties | ⊚ | ⊚ | ⊚ | ⊚ | ⊚ | ⊚ |

In summary, in the disclosure, the free radical polymerizable resin is introduced into the resin composition to reduce the number of polar functional groups contained in the epoxy resin system. In this way, the dielectric properties can be effectively reduced, thereby optimizing the electrical performance of the epoxy resin system and simultaneously meeting the requirements for copper-clad adhesion and film-forming properties.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A resin composition, comprising:
an epoxy resin;
an active ester compound;
a free radical polymerizable resin, comprising an olefin compound, wherein the olefin compound comprises a methacrylic compound, a styrene compound, an allyl compound, or a combination thereof;
an inorganic filler material; and
an accelerator.

2. The resin composition according to claim 1, wherein the free radical polymerizable resin is selected from at least two of the methacrylic compound, the styrene compound, and the allyl compound.

3. The resin composition according to claim 1, wherein at least one compound in the free radical polymerizable resin is the methacrylic compound.

4. The resin composition according to claim 3, wherein a weight proportion of the methacrylic compound in the resin composition is between 1 wt % and 10 wt %.

5. The resin composition according to claim 1, wherein a weight proportion of the epoxy resin in the resin composition is between 5 wt % and 15 wt %, a weight proportion of the active ester compound in the resin composition is between 10 wt % and 20 wt %, a weight proportion of the inorganic filler material in the resin composition is greater than 60 wt %, a weight proportion of the free radical polymerizable resin in the resin composition is between 1 wt % and 20 wt %, and a weight proportion of the accelerator in the resin composition is between 0.1 wt % and 0.5 wt %.

6. The resin composition according to claim 1, wherein the epoxy resin comprises a biphenyl aralkyl type epoxy resin, a bisphenol A type epoxy resin, or a combination thereof, the active ester compound comprises a polyester resin, the inorganic filler material comprises spherical silica, and the accelerator comprises 4-dimethylaminopyridine.

7. The resin composition according to claim 1, wherein a usage amount of the inorganic filler material in the resin composition is greater than a usage amount of the epoxy resin, the active ester compound, the free radical polymerizable resin, and the accelerator in the resin composition.

8. The resin composition according to claim 1, wherein a usage amount of the free radical polymerizable resin in the resin composition is greater than a usage amount of the accelerator in the resin composition.

9. The resin composition according to claim 1, wherein a usage amount of the free radical polymerizable resin in the resin composition is less than a usage amount of the epoxy resin in the resin composition.

10. The resin composition according to claim 1, wherein the olefin compound comprises a methacrylate polyphenylene ether resin, a hydrogenated styrenic elastomer, a vinyl benzyl polyphenylene ether resin, a hydrocarbon resin, a polybutadiene resin, or a combination thereof.
